(19) United States
(12) Patent Application Publication
(10) Pub. No.: US 2018/0248567 A1
(43) Pub. Date: Aug. 30, 2018

(54) METHOD FOR ERROR-CORRECTION CODING

(71) Applicant: HUAZHONG UNIVERSITY OF SCIENCE AND TECHNOLOGY, Wuhan (CN)

(72) Inventors: Daiming QU, Wuhan (CN); Tao WANG, Wuhan (CN); Tao JIANG, Wuhan (CN)

(21) Appl. No.: 15/965,855

(22) Filed: Apr. 28, 2018

Related U.S. Application Data
(63) Continuation-in-part of application No. PCT/CN2016/108511, filed on Dec. 5, 2016.

(30) Foreign Application Priority Data
Dec. 23, 2015 (CN) 201510995761.X
Sep. 21, 2016 (CN) 201610847488.0

(51) Int. Cl. H03M 13/29; H03M 13/11

(52) U.S. Cl. CPC H03M 13/2906; H03M 13/11

(57) ABSTRACT

An error-correction coding method based on concatenation of polar codes and repetition codes or multi-bit parity-check codes is proposed. The method includes: performing repetition coding or multi-bit parity-check coding on an information bit sequence, to yield an outer codeword; sequentially mapping a first bit to a last bit of the outer codeword on a first unfrozen bit to a last unfrozen bit of a polar code, to yield an unfrozen bit sequence; and performing polar coding on the unfrozen bit sequence, to yield a concatenated codeword.

### CROSS-REFERENCE TO RELATED APPLICATIONS

This application is a continuation-in-part of International Patent Application No. PCT/CN2016/108511 with an international filing date of Dec. 5, 2016, designating the United States, now pending, and further claims foreign priority benefits to Chinese Patent Application No. 201510995761.X filed Dec. 23, 2015, and to Chinese Patent Application No. 201610847488.0 filed Sep. 21, 2016. The contents of all of the aforementioned applications, including any intervening amendments thereto, are incorporated herein by reference. Inquiries from the public to applicants or assignees concerning this document or the related applications should be directed to: Matthias Scholl P.C., Attn.: Dr. Matthias Scholl Esq., 245 First Street, 18th Floor, Cambridge, Mass. 02142.

### BACKGROUND OF THE INVENTION

### Field of the Invention

The disclosure relates to the field of error-correction coding, and more particularly to an error-correction coding method based on concatenation of polar codes and repetition codes or multi-bit parity-check codes.

### Description of the Related Art

Polar coding are the first coding schemes that probably achieve the Shannon capacity with low encoding and decoding complexity, which makes it possible to put into practice. Simulation results show that a Successive Cancellation List (SCL) decoder can achieve the error correction performance of maximum likelihood decoder under a low complexity of O(L·N log(N)) (where L is the maximum number of paths in the SCL decoder and N is the codeword length). However, the error correction performance of polar codes with short and moderate codeword length under SCL decoding algorithm is mediocre, which is far from Shannon capacity, and cannot be balanced by simply increasing the maximum number of paths.

With regard to traditional polar code concatenation methods, the concatenated Low-Density Parity-Check (LDPC) codes do not exhibit an improved error correction performance compared to the Cyclical Redundancy Check (CRC)-concatenated polar codes under the CRC-aided SCL decoder, because the characteristics of the resultant concatenated codes are not suitable for the SCL decoder. The concatenated CRC codes require additional CRC checking circuits, which involves added hardware costs, and the error correcting capability is limited. Therefore, conventional polar concatenation schemes restrict the engineering applications of polar codes.

### SUMMARY OF THE INVENTION

In view of the above-described problems, it is one objective of the invention to provide an error-correction coding method based on concatenation of polar codes and repetition codes or multi-bit parity-check codes. The method aims to concatenate polar codes with an outer encoder of a low coding complexity to improve the error correcting capability of the polar code using a SCL decoding algorithm without increasing the decoding complexity and storing complexity.

To achieve the above objective, in accordance with one embodiment of the invention, there is provided an error-correction coding method based on concatenation of polar codes and repetition codes or multi-bit parity-check codes, the method comprising:
(1) performing repetition coding or multi-bit parity-check coding on an information bit sequence, to yield an outer codeword;
(2) sequentially mapping a first bit to a last bit of the outer codeword on a first unfrozen bit to a last unfrozen bit of a polar code, to yield an unfrozen bit sequence; and
(3) performing polar coding on the unfrozen bit sequence, to yield a concatenated codeword.

In a class of this embodiment, in (1), an information bit to be repeated is repeated one or more times during the repetition coding.

In a class of this embodiment, in (2), in the process of mapping, the bit channel capacities of unfrozen bit channels mapped by repeated bits are lower than those of the unfrozen bit channels mapped by unrepeated bits, where the repeated bits denote the information bits that are repeated in the repetition coding, and the unrepeated bits denote the information bits that are not repeated.

In a class of this embodiment, in (2), in the process of mapping, the indexes of the unfrozen bits mapped by the repeating bits of the outer codeword are greater than the index of the unfrozen bit mapped by the repeated bit corresponding to the repeating bits, where the repeating bits denotes the bits in the repetition code that repeat the repeated bit.

In a class of this embodiment, the repeating bits of the outer codeword are distributed uniformly or approximately uniformly in the unfrozen bit sequence obtained in (2).

In a class of this embodiment, by dividing the unfrozen bit sequence into S segments in the order of the indexes, the repeating bits of the outer codeword are mapped to Kₕ unfrozen bit channels of the lowest bit channel capacities in each segment, with the same number or approximately the same number of repeating bits in each segment, such that the repeating bits of the outer codeword are distributed uniformly or approximately uniformly in the unfrozen bits, where h=1, 2, . . . , S.

In a class of this embodiment, the outer code is replaced with an inverted repetition code. When the repeated bit is 1, the repeating bit of the inverted repetition code is 0, and when the repeated bit is 0, the repeating bit of the inverted repetition code is 1;

Assume that the repeated bit is repeated K times, the number of inversed repeating bits out of the K repeating bits obtained by repetition coding is 0˜K.

In a class of this embodiment, certain bits at the end of the outer codeword are used as parity bits, and each of the parity bits serves as an even or odd-parity bit for the information bits, where an even parity bit denotes a bit whose value is 0 (or 1) if the number of 1s in its corresponding information bits is even (or odd), an odd parity bit denotes a bit whose value is 1 (or 0) if the number of 1s in its corresponding information bits is even (or odd).

In a class of this embodiment, the error-correction coding method further comprises a decoding process as follows:

(4) deciding an original information bit according to the SCL decoding algorithm; and deciding the repeating bit directly based on a decision result of the repeated bit.

In a class of this embodiment, the decoding process for the error-correction coding method described above comprises:

Step (4.1) determining whether i is less than or equal to N; and if so, proceeding to Step (4.2), otherwise, proceeding to Step (4.7);

where N is the codeword length of the concatenated code, and i is the index of the i^{th} bit currently being decoded, and has an initial value of 1 and is assigned with a positive integer from 1 to N;

Step (4.2) determining whether uᵢ is a frozen bit, and if so, proceeding to Step (4.3), otherwise, proceeding to Step (4.4), where uᵢ is the i^{th} bit in the polar encoding bit sequence u₁^{N} and u₁^{N} is a row vector (u₁, u₂, u₃, . . . , u_{N}) in 1×N;

Step (4.3) setting the decision value for uᵢ on each path to the value of a known frozen bit, letting i=i+1, and returning to Step (4.1);

Step (4.4) determining whether uᵢ is the repeating bit of the j(1≤j≤K)^{th} repetition code, and if so, proceeding to Step (4.5), otherwise, proceeding to Step (4.6), where K is the number of repeated bits in the outer code, and the outer code contains K repetition codes, each of which consists of a repeated bit and the repeating bits corresponding to the repeated bit, and the j(1≤j≤K)^{th} repetition code in the outer code denotes the repetition code containing the j^{th} repeated bit;

Step (4.5) setting the decision value for the repeating bits uᵢ on each current path to the decision value of the repeated bit corresponding to uᵢ on the path, specifically,

$${\hat{u}}_{i} = {\hat{u}}_{m i n ( {A}_{{T}_{j}} )} ,$$

letting i=i+1, and returning to Step (4.1);

where Tⱼ is a set of indexes of all the bits in the j^{th} repetition code in the outer codeword, A_{T}_{ⱼ} is a set of indexes of all the bits in the j^{th} repetition code in the polar encoding bit sequence u₁^{N} after outer codeword mapping, and min(A_{T}_{ⱼ}) is the minimum element in the value set A_{T}_{ⱼ} and corresponds to the repeated bit in the j^{th} repetition code; throughout this disclosure, min(X) denotes the minimum value in the value set X;

Step (4.6) denoting the number of current paths as L′, obtaining 2L′ subpaths by assigning a value of 0 or 1 to uᵢ on each current path, and determining whether 2L′≤L is satisfied, and if so, reserving 2L′ subpaths, otherwise, reserving L subpaths with the maximum path metrics, letting i=i+1 and returning to Step (4.1);

where the path metrics of the 2L′ subpaths are respectively the probabilities W_{N}⁽ⁱ⁾(y₁^{N},û₁ⁱ⁻¹|0) or W_{N}⁽ⁱ⁾(y₁^{N},û₁ⁱ⁻¹|1) of assigning 0 or 1 to uᵢ on the paths, L is the maximum number of paths in the SCL decoding algorithm, and y₁^{N} denotes the received vector;

Step (4.7) obtaining a decoding result by outputting a decision sequence û₁^{N} corresponding to the path with the maximum path metric out of the L paths.

In a class of this embodiment, the parity bits of the outer codeword obtained by performing multi-bit parity-check coding on the information bit sequence in (1) are concentrated at the end of the outer codeword;

the set of indexes of the parity bits is P={M+1, M+2, M+3, . . . , M+K}, and the elements in the set P represent the bit indexes in the outer code where the parity bits are located. That is, in the codeword x₁^{M+K} generated by an outer encoder, the bit sequence x₁^{M} is comprised of information bits, and the bit sequence x_{M+1}^{M+K} is comprised of parity bits;

where M is the number of information bits, and K is the number of parity bits.

In a class of this embodiment, the parity bits of the outer codeword obtained by performing multi-bit parity-check coding on the information bit sequence in (1) are distributed uniformly in the outer codeword;

the interval between adjacent parity bits is

$$⌊ \frac{M + K}{K} ⌋ ,$$

and the set of indexes of the parity bits is

$$P = \{ ⌊ \frac{M + K}{K} ⌋ \cdot j , j = 1 , 2 , 3 … , K \} ;$$

where M is the number of information bits, K is the number of parity bits, M+K is the codeword length of the outer code, and └x┘ is a floor function of x.

In a class of this embodiment, the parity bits of the outer codeword obtained by performing multi-bit parity-check coding on the information bit sequence in (1) are non-uniformly distributed in the outer codeword.

In a class of this embodiment, in (1), the closer to the beginning of the outer codeword, the more dispersed the distribution of the parity bits, and the closer to the end of the outer codeword, the more concentrated the distribution of the parity bits. Therefore, a set P of indexes of the parity bits are obtained according to this characteristic of parity bit location distribution.

In a class of this embodiment, assuming that the number of parity bits concentrated at the end of the outer codeword is K₁, and the number of the other parity bits distributed uniformly is K−K₁, then the set of indexes of the parity bits is:

$$P = \{ {P}_{1} ⋃ {P}_{2} \vert {P}_{1} = \{ M + K - {K}_{1} + 1 , M + K - {K}_{1} + 2 , … , M + K \} , \\ {P}_{2} = \{ ⌊ \frac{M + K - K}{K - {K}_{1}} ⌋ \cdot j , j = 1 , 2 , 3 , … , K - {K}_{1} \} \} ;$$

where M is the number of information bits, and K is the number of parity bits.

In a class of this embodiment, when multi-bit parity-check coding is performed on the information bit sequence in (1), the parity bit is used only to check the information bits before and not the information bits after.

In a class of this embodiment, the outer code may be replaced with a multi-bit odd-parity code, whose parity bits are odd parity bits.

In a class of this embodiment, the decoding process for the coding method described above is performed by using a modified SCL decoding algorithm. Specifically, in decoding an information bit, bit decision is performed according to the SCL decoding algorithm, and in decoding a parity bit, decision is made by checking result based on the decision values of the information bits in the parity function containing the parity bit, where a parity function denotes the mathematical relationship between a parity bit and its corresponding information bits.

In a class of this embodiment, the decoding process comprises:

Step 1: determining whether i is less than or equal to N, and if so, proceeding to Step 2, otherwise, proceeding to Step 7, where N is the codeword length of the concatenated code, and i is the index of the i^{th} bit being decoded, and has an initial value of 1 and is assigned with a positive integer from 1 and N;

Step 2: determining whether uᵢ is a frozen bit, and if so, proceeding to Step 3, otherwise, proceeding to Step 4, where uᵢ is the i^{th} bit in the polar encoding bit sequence;

Step 3: setting the decision value for uᵢ on each current path to the value of a known frozen bit, letting i=i+1, and returning to Step 1;

Step 4: determining whether uᵢ is the j(j=1, 2, . . . , K)^{th} parity bit, and if so, proceeding to Step 5, otherwise, proceeding to Step 6, where K is the number of parity bits;

Step 5: obtaining a decision value for uᵢ on each current path by checking result based on the decision values of the information bits on the path:

$${\hat{u}}_{i} ( {\sum }_{h ∈ {A}_{{T}_{j}} \backslash max ( {A}_{{T}_{j}} )} {\hat{u}}_{h} ) mod 2 ,$$

letting i=i+1, and returning to Step 1; where Tⱼ is a set of indexes of all the bits in the j^{th} parity function in the outer code, and the outer code contains K parity functions, each of which consists of a parity bit and the information bits corresponding to the parity bit, and the j^{th} parity function denotes a parity function containing the j^{th} parity bit, A_{T}_{ⱼ} is a set of indexes of all the bits in the j^{th} parity function in the polar encoding bit sequence u₁^{N} after outer codeword mapping, max(A_{T}_{ⱼ}) denotes the maximum element in the value set A_{T}_{ⱼ} and it is the index of the parity bit in the j^{th} parity function mapped into u₁^{N}; h is a temporary variable in said sum operation, denoting each element in the set A_{T}_{ⱼ}\max(A_{T}_{ⱼ}) sequentially, and A_{T}_{ⱼ}\max(A_{T}_{ⱼ}) denotes the difference between the value sets A_{T}_{ⱼ} and max(A_{T}_{ⱼ}), where A_{T}_{ⱼ}\max(A_{T}_{ⱼ})={λ|λ∈A_{T}_{ⱼ},λ≠max(A_{T}_{ⱼ})};

Throughout this disclosure, max(X) denotes the maximum element in the value set X, and {X\Y} denotes the difference between the value sets X and Y, i.e., {X\Y}={λ|λ∈X,λ∉Y};

Step 6: denoting the number of current paths as L′, and obtaining 2L′ subpaths by assigning a value of 0 or 1 to uᵢ on each current path, where the path metrics for the 2L′ subpaths are respectively the probabilities W_{N}⁽ⁱ⁾(y₁^{N},û₁ⁱ⁻¹|0) or W_{N}⁽ⁱ⁾(y₁^{N},û₁ⁱ⁻¹|1) of assigning 0 or 1 to uᵢ on the paths, and y₁^{N} denotes the received vector;

if 2L′≤L, reserving 2L′ subpaths, otherwise, if 2L′>L, reserving L subpaths with the maximum path metrics, letting i=i+1 and returning Step 1;

where L is the maximum number of paths in the SCL decoding algorithm;

Step 7: outputting the decision sequence û₁^{N} corresponding to the path with the maximum path metric out of the L paths;

Step 8: end.

In general, compared with conventional techniques, the above-described technical solution conceived by the disclosure can achieve the following beneficial effects:

(1) The present scheme improves the error correcting capability of the polar code significantly;

The non-concatenated polar code of a short-to-moderate codeword length that uses a SCL decoding algorithm has an error correcting capability approaching the decoding capability of a maximum-likelihood decoder. Its error correcting capability is limited. Furthermore, even if the maximum number of paths in the SCL decoding algorithm is increased, the Frame Error Rate cannot be improved significantly. Also, increasing the maximum number of paths linearly increases the storing complexity and the decoding complexity of the algorithm, which is not beneficial for engineering implementation. Using a SCL decoding algorithm with the same maximum number of paths, the concatenated scheme provided by the disclosure exhibits an error correcting capability that is significantly improved over that of a non-concatenated polar code, and also outperforms the CRC-concatenated polar code.

(2) The present scheme causes no noticeable increase in decoding complexity and storing complexity;

In terms of the scheme concatenating a polar code with a multi-bit parity-check code, the essential difference between the modified SCL decoding algorithm adopted by the present solution and the original SCL decoding algorithm lies in that: the present algorithm decodes the parity bit directly by checking result based on the decision values of the information bits in the parity function. Since the number of parity functions and the length of the parity function are much smaller than the concatenated codeword length, the increase in decoding complexity is negligible. Although the present solution involves a slight increase in the storing complexity, that is, the parity functions for the outer code need to be stored in both the encoder and the decoder, the storage space occupied by the parity functions is rather small for the overall system since the number of parity functions and the length of the parity function for the outer code are much smaller than the concatenated codeword length. In terms of the solution concatenating a polar code with a repetition code, the essential difference lies in that the present algorithm decodes the repeating bit directly by decision result of the repeated bit. Compared with decoding by using a conventional SCL decoding algorithm, this modified decoding method according to the disclosure simply determines the value of the repeating bit as the value of the repeated bit, which involves operational complexity that is similar to that of decision of a frozen bit as 0 according to the conventional SCL algorithm. Therefore, the operational complexity is not increased.

(3) The outer code of the present solution is simple and easy to be implemented;

The present solution uses a repetition code or a multi-bit parity-check code as the outer code. Compared with solutions using other outer codes, the method according to the disclosure allows for a simple design of the hardware circuit in the outer encoder, thereby facilitating engineering implementation.

### BRIEF DESCRIPTION OF THE DRAWINGS

FIG. 1 is a schematic view showing a decoding process of a polar code with a codeword length of 4 by using a conventional SCL decoding algorithm;

FIG. 2 is a flow diagram of the encoding and decoding process in an error-correction coding method based on concatenation of polar codes and repetition codes or multi-bit parity-check codes according to the disclosure;

FIG. 3 is a schematic view showing a decoding process of an error-correction coding method based on concatenation of repetition codes and polar codes with a codeword length of 4;

FIG. 4 is a schematic view showing an encoding process of an outer codeword in an error-correction coding method concatenating a polar code with a repetition code according to an embodiment of the disclosure; and

FIGS. 5A-5C show three examples of determining the locations of parity bits in a parity-check code according to an embodiment of the disclosure.

### DETAILED DESCRIPTION OF THE EMBODIMENTS

For further illustrating the invention, examples detailing an error-correction coding method based on concatenation of polar codes and repetition codes or multi-bit parity-check codes are described below. It should be noted that the following examples are intended to describe and not to limit the invention.

For a polar code of a codeword length of N and with a number M of transmitted information bits, polar coding is performed by polarizing N independent identically distributed channels into N bit channels by the channel polarization. Of the N bit channels, the information bits are transmitted over the M bit channels with the largest bit channel capacities, which are referred to as unfrozen bit channels, and a bit transmitted over an unfrozen bit channel is referred to as an unfrozen bit. The other (N−M) bit channels are referred to as frozen bit channels, and a bit transmitted over a frozen bit channel is referred to as a frozen bit.

The polar encoding bit sequence is u₁^{N}=(u₁, u₂, u₃, . . . , u_{N}). Bits u₁ to u_{N} are transmitted sequentially over the 1^{st} to the N^{th} bit channels. The set of indexes of the unfrozen bits in u₁^{N} is A={a₁, a₂, a₃, . . . , a_{M}}⊆{1, 2, 3, . . . , N}. The elements in the set A satisfy the condition that when 1≤i<j≤M, then aᵢ<aⱼ. The set of indexes of the frozen bits in u₁^{N} is A^{c};

The unfrozen bit sequence is u_{A}=(uₐ_{₁}, uₐ_{₂}, uₐ_{₃}, . . . , uₐ_{_{M}}). The frozen bits in the polar code are known at both the transmitter and the receiver. For symmetric channels, the frozen bit sequence u_{A}_{^{c}} is set to a sequence of all 0s. If M information bits are known, the unfrozen bit sequence u_{A} can be determined, and therefore the polar encoding bit sequence u₁^{N} can also be determined. The polar codeword is c₁^{N}=u₁^{N}G_{N}, where G_{N} is a polar code generator matrix.

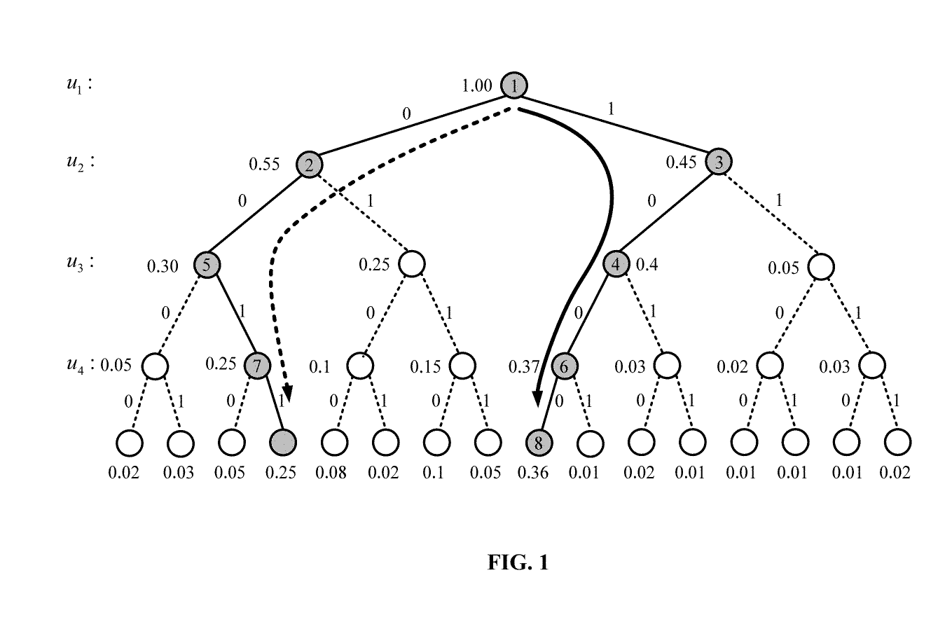

In decoding, the SCL decoding algorithm decides the bits u₁ to u_{N} sequentially. During decoding by using the SCL algorithm, at most L decoding paths may be reserved in the decoder list. When decoding uᵢ, each path is uniquely identified by the sequence û₁ⁱ⁻¹ that has been decoded on the path. FIG. 1 is a schematic view showing a decoding process of a polar code with a codeword length of 4 by using a SCL decoding algorithm, where u₂ is a frozen bit, (u₁,u₃,u₄) are unfrozen bits, and the maximum number of paths is L=2. In decoding, the frozen bit u₂ on each path is determined as 0, and unfrozen bits are determined based on the path metrics. The process comprises specifically the following steps:

In Step 1, it is determined whether i is less than or equal to N. If so, proceed to Step 2. Otherwise, proceed to Step 5. The initial value of i is 1.

In Step 2, it is determined whether uᵢ is a frozen bit. If so, proceed to Step 3. Otherwise, proceed to Step 4.

In Step 3, the decision value for uᵢ on each current path is set to 0. Let i=i+1, and return to Step 1.

In Step 4, the number of current paths is denoted as L′. A value of 0 or 1 may be assigned to uᵢ on each current path so as to obtain 2L′ subpaths. If 2L′≤L, 2L′ subpaths are reserved. If 2L′>L, L subpaths with the maximum path metrics are reserved. Let i=i+1, and return to Step 1.

The path metrics for each of the 2L′ subpaths are respectively the probabilities of assigning a value of 0 or 1 to uᵢ on the path: W_{N}⁽ⁱ⁾(y₁^{N},û₁ⁱ⁻¹|0) or W_{N}⁽ⁱ⁾(y₁^{N},û₁ⁱ⁻¹|1). L is the maximum number of paths in the SCL decoder, and y₁^{N} denotes the received vector.

In Step 5, a decision sequence û₁^{N} for the path with the maximum path metric out of the L paths is output. The unfrozen bit sequence û_{A} in the decision sequence û₁^{N} is the decoding result for the information bit sequence in the polar code.

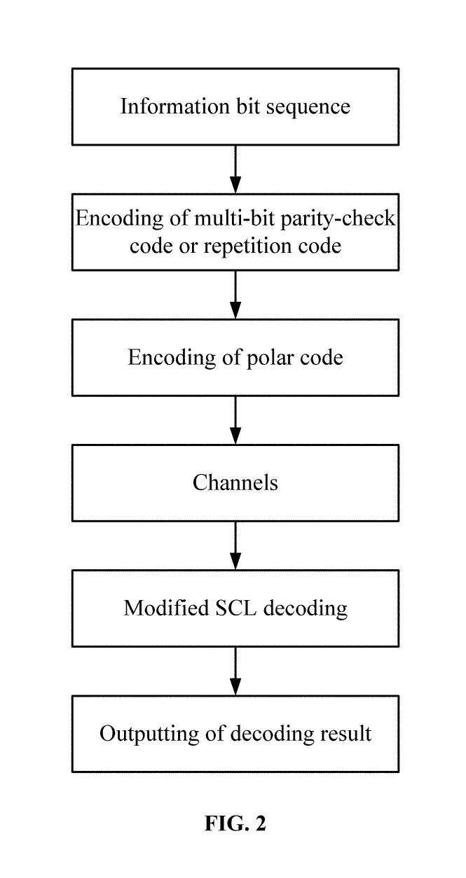

FIG. 2 shows a flow diagram of an error-correction coding method concatenating a polar code with a repetition code or multi-bit parity-check code according to the disclosure, specifically comprising the following steps.
(1) performing repetition coding or multi-bit parity-check coding on an information bit sequence, to yield an outer codeword;
(2) sequentially mapping a first bit to a last bit of the outer codeword on a first unfrozen bit to a last unfrozen bit of a polar code, to yield an unfrozen bit sequence; and
(3) performing polar coding on the unfrozen bit sequence, to yield a concatenated codeword.

The error-correction coding method concatenating a polar code with a repetition code and the error-correction coding method concatenating a polar code with a multi-bit parity-check code are explained below.

The error-correction coding method concatenating a polar code with repetition codes comprises the following steps.

Step 1: Encoding by an Outer Encoder

For a concatenation system with a codeword length N, a number of information bits M, a number of repeated bits K₁(K₁≤M), and a number of repeating bit K₂ (K₂≥K₁), the input of the outer encoder is M information bits and the length of the output outer codeword is M+K₂, where the repeated bits denote the information bits that are repeated in the repetition coding and the repeating bits denotes the bits in the repetition code that repeat the repeated bit. In the concatenation system of a polar code with repetition codes, the outer code contains K₁ repetition codes, each of which consists of a repeated bit and the repeating bits corresponding to the repeated bit, and the j(1≤j≤K₁)^{th} repetition code in the outer code denotes the repetition code containing the j^{th} repeated bit;

The codeword obtained by the outer encoder is x₁^{M+K}^{₂}. x₁^{M+K}^{₂} contains M information bits and K₂ repeating bits. Determination of the outer encoder is equivalent to determination of the indexes of the K₁ repeated bits in the outer codeword x₁^{M+K}^{₂} and the indexes of the repeating bits each corresponding to a repeated bit. The index of the j(1≤j≤K₁)^{th} repeated bit and the indexes of the corresponding repeating bits in the outer codeword are denoted as a set Tⱼ(1≤j≤K₁). It is appreciated that each set Tⱼ identifies a |Tⱼ|-element repetition code in the outer codeword. |Tⱼ| denotes the number of elements in the set Tⱼ, and |Tⱼ|=2 indicates that Tⱼ identifies a two-element repetition code. The minimum element in the set Tⱼ denotes the index of the repeated bit, and the other elements denote the indexes of the repeating bits of the repetition code.

Taking an outer codeword in which each repetition code is a two-element repetition code as an example, i.e., K₁=K₂, the construction of the set Tⱼ (1≤j≤K₁) will be described. It is to be noted that the specific construction of the set Tⱼ(1≤j≤K₁) is intended merely for illustration rather than limitation of the disclosure.

(1.1) segmentation of the outer codeword and determination of the number of repeating bits and repeated bits in each segment:

First, the outer codeword is divided into S segments in the order of bit indexes, in such a manner that K₁ repeating bits are allotted equally to the 2^{nd} through the S^{th} segments, where the number of repeating bits allotted to the h(2≤h≤S−1)^{th} segment is └K₁/(S−1)┘ (with └x┘ representing a floor function of x), and the number of repeating bits allotted to the h(h=S)^{th} segment is K₁−(S−2)└K₁/(S−1)┘ (such that each segment contains an integer number of repeating bits, and there is a total number of K₁ repeating bits);

The repeating bits in the h(2≤h≤S)^{th} segment are used to check the repeated bits in the h−1^{th} segment. The h′(1≤h′≤S−2)^{th} segment contains a number of └K₁/(S−1)┘ repeated bits, and the h′(h′=S−1)^{th} segment contains a number of K₁−(S−2)└K₁/(S−1)┘ repeated bits;

(1.2) determination of the indexes of repeating bits and repeated bits in each segment based on the number of repeating bits and the number of repeated bits in each segment:

According to outer codeword mapping, the bit channel capacity of the unfrozen bit channel to which each bit in the outer codeword is mapped is known. The expression “bit with high (low) bit channel capacity” refers to “bit of the outer codeword that is transmitted over the unfrozen bit channel with high (low) bit channel capacity after outer codeword mapping”.

The repeating bits are selected in such a manner that the └K₁/(S−1)┘ bits with the lowest bit channel capacities in the h(2≤h≤S−1)^{th} segment are selected as the repeating bits, and the K₁−(S−2)└K₁/(S−1)┘ bits with the lowest bit channel capacities in the h(h=S)^{th} segment are selected as the repeating bits.

The repeated bits are selected in such a manner that with the repeating bits that have been selected in the h′(1≤h′≤S−2)^{th} segment removed, the └K₁/(S−1)┘ bits with the lowest bit channel capacities out of the remaining bits are selected as the repeated bits in the segment; and with the repeating bits that have been selected in the h′(h′=S−1)^{th} segment removed, the K₁−(S−2)└K₁/(S−1)┘ bits with the lowest bit channel capacities out of the remaining bits are selected as the repeated bits in the segment;

(1.3) pairing the repeating bits in the h(2≤h≤S)^{th} segment with the repeated bits in the h−1^{th} segment, in such a manner that the repeating bit with the lowest bit channel capacity in the h(2≤h≤S)^{th} segment is paired with the repeated bit with the lowest bit channel capacity in the h−1^{th} segment, so that a set Tⱼ is constructed from the indexes of the corresponding repeating bits and repeated bits; then pairing the repeating bit with the second lowest bit channel capacity in the h(2≤h≤S)^{th} segment with the repeated bit with the second lowest bit channel capacity in the h−1^{th} segment, and so on, until all the K₁ repeated bits have been paired so as to obtain K₁ sets Tⱼ(1≤j≤K₁) of two-element repetition codes;

(1.4) outer encoding is based on the sets Tⱼ(1≤j≤K₁), that is, the value of the repeating bits with indexes {Tⱼ\min(Tⱼ)}(1≤j≤K₁) in the outer codeword is equal to the value of the repeated bit with index min(Tⱼ)(1≤j≤K₁), i.e., xᵢ=x_{min(T}_{ⱼ}₎, (i∈{Tⱼ\min(Tⱼ)},1≤j≤K₁). Based on the information bits and Tⱼ(1≤j≤K₁), values of the K₁ repeating bits are determined, and consequently the outer codeword x₁^{M+K}^{₁} can be determined.

Step 2: Outer Codeword Mapping

Outer codeword mapping is a process in which the bits of the outer codeword are mapped to the bits in a polar encoding bit sequence u₁^{N}. The set of indexes of the unfrozen bits in u₁^{N} is A={a₁, a₂, a₃, . . . , a_{M+K}_{₂}}⊆{1, 2, 3, . . . , N}, the set of indexes of the frozen bits is A^{c}, and the unfrozen bit sequence in the polar code is

$${u}_{A} = ( {u}_{{a}_{1}} , {u}_{{a}_{2}} , {u}_{{a}_{3}} , … , {u}_{{a}_{M + {K}_{2}}} ) ,$$

where all the frozen bits are assigned with 0;

The outer codeword x₁^{M+K}^{₂} is mapped to an unfrozen bit sequence u_{A} in such a manner that the first bit x₁ through the last bit x_{M+K}_{₂} in the outer codeword are mapped sequentially to the first bit uₐ_{₁} through the last bit

$${u}_{i} = {u}_{{a}_{M + {K}_{2}}}$$

in the unfrozen bit sequence, that is, uₐ_{ₖ}=xₖ, (k=1, 2, 3, . . . , M+K₂) or u_{A}=x₁^{M+K}^{₂};

After mapping, the j(1≤j≤K₁)^{th} repeated bit in the outer codeword is transmitted over the unfrozen bit channel a_{min(T}_{ⱼ}₎={aᵢ|i=min(Tⱼ)}, and the repeating bit corresponding to the j(1≤j≤K₁)^{th} repeated bit in the outer codeword is transmitted over the unfrozen bit channel a_{T}_{ⱼ}_{\min(T}_{ⱼ}₎={aᵢ|i∈Tⱼ\min(Tⱼ)}.

Step 3: Encoding by the Inner Encoder.

The unfrozen bit sequence for the inner polar code obtained in Step 2 is u_{A}=x₁^{M+K}^{₂}, and the frozen bit sequence for the polar code is comprised totally of 0s, from which a polar encoding bit sequence u₁^{N} is derived. Based on the polar coding formula, a codeword c₁^{N}=u₁^{N}G_{N} encoded by the concatenation system is obtained, where G_{N} is a polar code generator matrix.

Step 4: Decoding at the Receiver

Decoding is performed by using the modified SCL decoding algorithm. The essential modification is that in decoding the repeating bit, decision is made directly based on the decision result of the repeated bit, rather than based on the path metrics as in the original SCL decoding algorithm. The decoding process comprises specifically the following steps.

(4.1) It is determined whether i is less than or equal to N. If so, proceed to (4.2). Otherwise, proceed to (4.7);

(4.2) It is determined whether uᵢ is a frozen bit. If so, proceed to (4.3). Otherwise, proceed to (4.4);

(4.3) The decision value for uᵢ on each current path is set to the value of a known frozen bit. Let i=i+1 and return to Step (4.1). In this embodiment, the frozen bit sequence is a sequence comprised totally of 0s. Therefore, the decision value for uᵢ on each current path is set to 0;

(4.4) It is determined whether uᵢ is the repeating bit of the j(1≤j≤K₁)^{th} repetition code. If so, proceed to (4.5). Otherwise, proceed to (4.6);

(4.5) The decision value for the repeating bit uᵢ on each current path is directly set to the decision value of the repeated bit corresponding to uᵢ on said path:

$${\hat{u}}_{i} = {\hat{u}}_{m i n ( {A}_{{T}_{j}} )} .$$

Let i=i+1 and return to (4.1);

Tⱼ denotes the set of indexes of all the bits of the j^{th} repetition code in the outer codeword, and A_{T}_{ⱼ} denotes the set of indexes of all the bits of the j^{th} repetition code in the polar encoding bit sequence uᵢ^{N} after outer codeword mapping, where the minimum element min(A_{T}_{ⱼ}) in A_{T}_{ⱼ} corresponds to the repeated bit in the j^{th} repetition code, and i∈{A_{T}_{ⱼ}\min(A_{T}_{ⱼ})} corresponds to the repeating bit of the j^{th} repetition code;

(4.6) The number of current paths is denoted as L′, and a value of 0 or 1 may be assigned to uᵢ on each current path, so as to obtain 2L′ subpaths. The path metrics of the 2L′ subpaths are respectively the probabilities of assigning a value of 0 or 1 to uᵢ on the paths: W_{N}⁽ⁱ⁾(y₁^{N},û₁ⁱ⁻¹|0) or W_{N}⁽ⁱ⁾(y₁^{N},û₁ⁱ⁻¹|1). If 2L′≤L (L is the maximum number of paths in the SCL decoding algorithm, and y₁^{N} denotes the received vector), the 2L′ subpaths are reserved. If 2L′>L, the L subpaths with the maximum path metrics are reserved. Let i=i+1 and return to (4.1);

(4.7) The decision sequence û₁^{N} for the path with the maximum path metric out of the L paths is output as the decoding result;

In the decoding result û₁^{N}, \hat{x}₁^{M+K}^{₂}=û_{A} denotes the decoding result for the outer codeword. Let the set I={i|i=1, 2, 3, . . . , M+K₂,i∉{Tⱼ\min(Tⱼ)},1≤j≤K₁}, and \hat{x}₁ denotes the decoding result for the transmitted information bits.

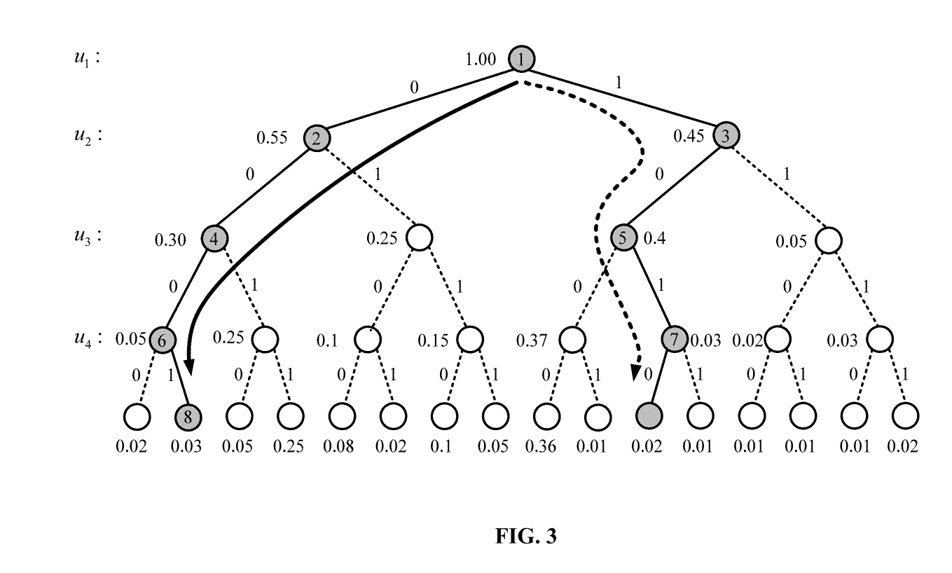

FIG. 3 is a schematic view showing a decoding process of a concatenated code of length 4 and a set A_{T}_{₁}={1, 3} of two-element repetition code by using a modified SCL (the maximum number of paths L=2) according to the disclosure. In decoding the bit u₃ on two paths, since u₃ is a repeating bit for the information bit u₁, the decision value for u₃ can be obtained directly based on the decision result of the repeated bit

$${u}_{1} = {u}_{m i n ( {A}_{{T}_{1}} )} ,$$

rather than by decision based on the path metrics of the SCL decoding algorithm.

The error-correction coding method concatenating a polar code with a repetition code is described below in detail in conjunction with an embodiment.

In this embodiment, the concatenated codeword length is N=16, the number of information bits is M=8, the number of repeated bits is K₁=4, and the number of repeating bits is K₂=4. The outer code contains a total of four two-element repetition codes (Tⱼ(1≤j≤4), each set Tⱼ containing 2 elements). There are 12 unfrozen bit channels in the inner polar code. The polar code is constructed at a given signal-to-noise ratio to obtain an index set A={a₁, a₂, a₃, . . . , a₁₂}⊆{1, 2, 3, . . . , 16} of the unfrozen bit channels and an index set A^{c} of the frozen bit channels. The decoder at the receiver adopts the modified SCL decoding algorithm, with the maximum number of paths set to L. The error-correction coding method concatenating a polar code with a repetition code according to this embodiment is described below in detail:

Step 1: Encoding by the Outer Encoder

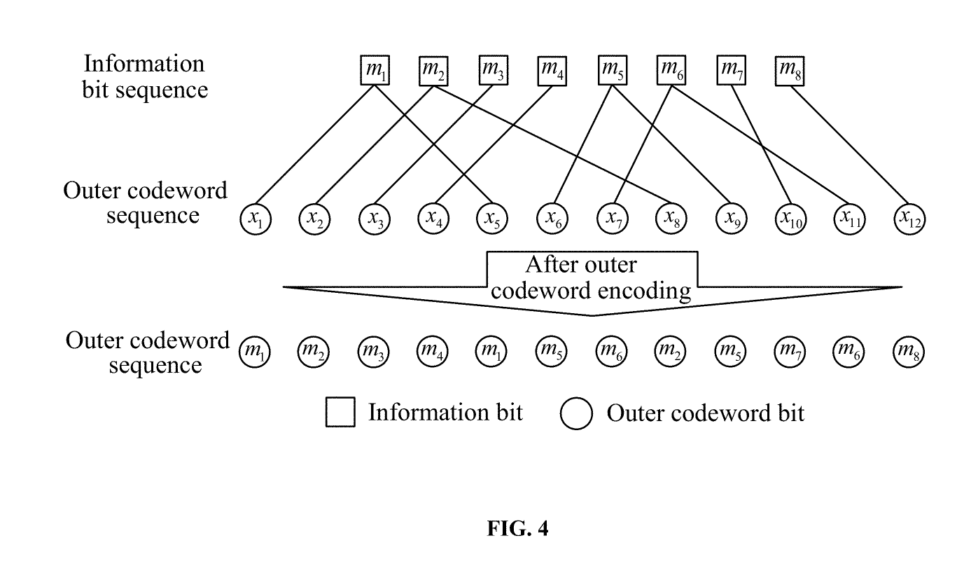

Assuming that the number of information bits is 8, the information bit sequence is m₁⁸=(m₁, m₂, m₃, . . . , m₈), and the number of repeating bits of the outer codeword is 4, then the outer codeword length is 12, and the outer codeword is denoted as x₁¹²=(x₁, x₂, x₃, . . . , x₁₂). As shown in FIG. 4, the 4 sets of two-element repetition codes are respectively: T₁={1, 5}, T₂={2, 8}, T₃={6, 9}, and T₄={7, 11}. In encoding by the outer encoder, the index set of 8 information bits in the outer codeword is presented as follows:

$$\begin{matrix}I = \{ i \vert i = 1 , 2 , 3 , … , M + {K}_{2} , i ∉ \{ {T}_{j} \backslash min ( {T}_{j} ) \} , 1 \leq j \leq {K}_{1} \} \\ = \{ i \vert i = 1 , 2 , 3 , … , 12 , i ∉ \{ {T}_{j} \backslash min ( {T}_{j} ) \} , 1 \leq j \leq 4 \} \\ = \{ i \vert i = 1 , 2 , 3 , … , 12 , i ∉ \{ 5 , 8 , 9 , 11 \} \} \\ = \{ 1 , 2 , 3 , 4 , 6 , 5 , 7 , 10 , 12 \}\end{matrix}$$

That is, x₁=m₁⁸. According to the set T₁={1, 5}, the repeating bit x₅ in outer codeword is x₅=x₁=m₁. The values of x₈=x₂=m₂, x₉=x₆=m₅, and x₁₁=x₇=m₆ are determined sequentially based on T₂, T₃, and T₄, and the outer codeword x₁¹²=(m₁, m₂, m₃, m₄, m₁, m₅, m₆, m₂, m₅, m₇, m₆, m₈) is determined accordingly. Thus encoding by the outer encoder is completed.

Step 2: Outer Codeword Mapping.

The codeword obtained by the outer encoder is x₁¹², and the index set of unfrozen bit channels in the polar code is A={a₁, a₂, a₃, . . . , a₁₂}. The 1^{st} through the 12^{th} bits in the codeword x₁¹² are mapped sequentially to the 1^{st} through the 12^{th} unfrozen bits in the polar code, resulting in an unfrozen bit sequence u_{A}=x₁¹² for the polar code;

After mapping, the j^{th} repeated bit in the outer codeword is transmitted over the unfrozen bit channel a_{min(T}_{ⱼ}₎, ={aᵢ|i=min(Tⱼ)}, (1≤j≤4), and the repeating bit corresponding to the j^{th} repeated bit in the outer code is transmitted over the unfrozen bit channel a_{T}_{ⱼ}_{\min(T}_{ⱼ}₎={aᵢ|i∈Tⱼ\min(Tⱼ)}.

With regard to the four sets Tⱼ(1≤j≤4) obtained in Step 1, the four repeated bits in the outer codeword are transmitted over the unfrozen bit channels a_{min(T}_{ⱼ}_{), 1≤j≤4}={a₁,a₂,a₆,a₇}, and the four repeating bits in the outer codeword are transmitted over the unfrozen bit channels a_{T}_{ⱼ}_{\min(T}_{ⱼ}_{), 1≤j≤4}={a₅,a₈,a₉,a₁₁}.

Step 3: Encoding by the Inner Encoder.

The unfrozen bit sequence for the inner polar code obtained in Step 2 is u_{A}=x₁¹², and the frozen bit sequence for the polar code is comprised totally of 0s, from which the polar encoding bit sequence u₁¹⁶ is derived. Based on the polar coding formula, a codeword encoded by the concatenation system c₁¹⁶=u₁¹⁶G₁₆ is obtained, where G₁₆ is a generator matrix of a polar code of length 16.

Step 4: Decoding by the Concatenation System.

In this embodiment, a modified SCL decoding method is used for decoding by the concatenation system. For a first set of two-element repetition codes T₁={1, 5}, when decoding the unfrozen bit uₐ_{₅}, the decision for the bit uₐ_{₅} in each path is obtained based on the decision value of the repeated bit uₐ_{₁}, i.e., ûₐ_{₅}=ûₐ_{₁}. For decision of a bit other than the repeating bits, decision is made according to the conventional SCL decoding algorithm. According to such a modified SCL decoding algorithm, the decoding result û₁¹⁶ is obtained for the code. In the decoding result û₁¹⁶, \hat{x}₁¹²=û_{A} is the decoding for the outer codeword. Let the set I={1,2,3,4,6,7,10,12}, then \hat{x}₁ is the decoding result for the transmitted information bits.

The error-correction coding method concatenating a polar code with a multi-bit parity-check code is described below in detail:

Step 1: Encoding by the Outer Encoder.

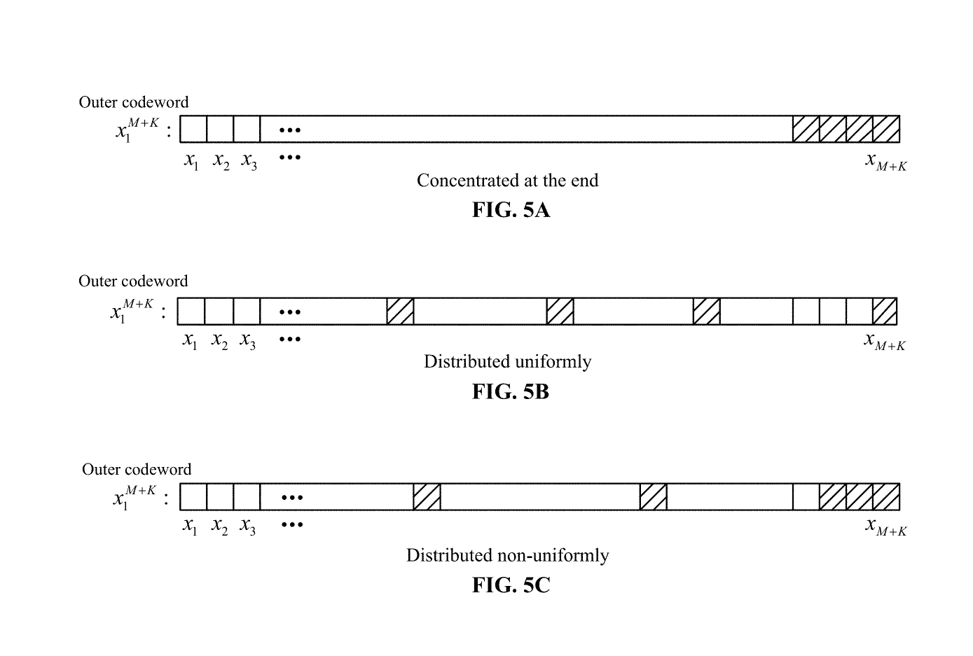

For a concatenation system with a codeword length N, a number of information bits M, and a number of parity bits K, the length of input information sequence for the outer code is M, and the length of output outer codeword is M+K. Assume that the outer codeword is x₁^{M+K}, and x₁^{M+K} contains M information bits and K parity bits. In the concatenation system of a polar code with a multi-bit parity-check code, the outer code contains K parity functions, each of which consists of a parity bit and the information bits corresponding to the parity bit, and the j(1≤j≤K)^{th} parity function in the outer code denotes the parity function containing the j^{th} parity bit; As shown in FIGS. 5A-5C, depending on the distribution of locations of the K parity bits of the outer codeword, the disclosure provides three methods for determining the locations of the parity bits:

Method 1: The parity bits are concentrated at the end of the outer codeword. As shown in FIG. 5A, the set of indexes of the parity bits is P={M+1, M+2, M+3, . . . , M+K}. The elements in the set P represent bit indexes in the outer code where the parity bits are located. That is, in the outer codeword x₁^{M+K}, the bit sequence x₁^{M} is comprised of information bits, and the bit sequence x_{M+1}^{M+K} is comprised of parity bits.

Method 2: The parity bits are distributed uniformly in the outer codeword. As shown in FIG. 5B, the codeword length of the outer code is M+K, the interval between adjacent parity bits is

$$⌊ \frac{M + K}{K} ⌋ ,$$

where └x┘ denotes a floor function of x, and the set of indexes of the parity bits is

$$P = \{ ⌊ \frac{M + K}{K} ⌋ \cdot j , j = 1 , 2 , 3 , … , K \} .$$

Method 3: The parity bits are distributed non-uniformly in the outer codeword. As shown in FIG. 5C, in this method, the distribution characteristic of parity bits in Method 3 is that the closer to the beginning of the outer codeword, the more dispersed the distribution of the parity bits, and the closer to the end of the outer codeword, the more concentrated the distribution of the parity bits. According to this characteristic of the distribution of the parity bit locations, an index set P of the parity bits is obtained.

In specific implementation, Method 3 may be a combination of Method 1 and Method 2 described above. Specifically, some parity bits are concentrated at the end, and the other parity bits are distributed uniformly. Assuming that the number of parity bits concentrated at the end is K₁, then the number of parity bits distributed uniformly at the front is K−K₁. It is obtained that the set of indexes of the parity bits is:

$$P = \{ {P}_{1} {UP}_{2} \vert {P}_{1} = \{ M + K - {K}_{1} + 1 , M + K - {K}_{1} + 2 , … , M + K \} , {P}_{2} = \{ ⌊ \frac{M + K - {K}_{1}}{K - {K}_{1}} ⌋ \cdot j , j = 1 , 2 , 3 , … , K - {K}_{1} \} \} .$$

When K₁=0, the set P₁ is an empty set, in which case Method 3 is equivalent to Method 1. When K₁=K, the set P₂ is an empty set, in which case Method 3 is equivalent to Method 2.

Assume that the index set of parity bits determined by using one of the three methods described above is denoted as P={p₁, p₂, p₃, . . . , P_{K}}⊆{1, 2, 3 . . . , M+K}, where pⱼ denotes the index of the j(j=1, 2, 3, . . . , K)^{th} parity bit among the bits of the outer codeword, and the set of indexes of all the bits from the parity function containing the parity bit xₚ_{ⱼ} in the outer codeword is denoted as Tⱼ, where Tⱼ satisfies Tⱼ⊆{1, 2, 3, . . . , pⱼ}, and pⱼ belongs to Tⱼ, i.e., pⱼ=max(Tⱼ), such that the parity bit only checks the information bits before and is irrelevant to the information bits after. The parity bit xₚ_{ⱼ} is assigned with a value of

$${x}_{{p}_{j}} = ( {\sum }_{i ∈ {T}_{j} \backslash ma x ( {T}_{j} )} {x}_{i} ) mod 2 , j = 1 , 2 , 3 , … , K .$$

Then encoding of the outer code is completed.

Step 2: Outer Codeword Mapping.

Outer codeword mapping is a process in which the bits of the outer codeword are mapped to the bits in a polar encoding bit sequence u₁^{N}. Assume that the set of indexes of the unfrozen bits in u₁^{N} is A={(a₁, a₂, a₃, . . . , a_{M+K}}⊆{1, 2, 3, . . . , N}), the set of indexes of the frozen bits in u₁^{N} is A^{c}, the unfrozen bit sequence in the polar code is u_{A}=(uₐ_{₁}, uₐ_{₂}, uₐ_{₃}, . . . , uₐ_{_{M+K}}), and all the frozen bits are assumed to be 0. The outer codeword x₁^{M+K} is mapped to the unfrozen bit sequence u_{A} in such a manner that the first bit x₁ through the last bit x_{M+K} in the outer codeword are mapped sequentially to the first bit uₐ_{₁} through the last bit uₐ_{_{M+K}} in the unfrozen bit sequence. That is, uₐ_{ₖ}=xₖ, (k=1, 2, 3, . . . , M+K) or u_{A}=x₁^{M+K}.

As is known after mapping, parity bits in the outer codeword are transmitted over the unfrozen bit channels A_{P}={aᵢ|i∈P}, the j(j=1, . . . , K)^{th} parity bit in the outer codeword is transmitted over the unfrozen bit channel aₚ_{ⱼ}, and all the bits in the j^{th} parity function of the outer codeword are transmitted over the unfrozen bit channels A_{T}_{ⱼ}={aᵢ|i∈Tⱼ}.

Step 3: Encoding by the Inner Encoder.

The unfrozen bit sequence in the inner polar code obtained in Step 2 is u_{A}=x₁^{M+K}, and the frozen bit sequence in the polar code is comprised totally of 0s, from which a polar encoding bit sequence u₁^{N} is derived. Based on the polar coding formula, a codeword encoded by the concatenation system c₁^{N}=u₁^{N}G_{N} is obtained, where G_{N} is a polar code generator matrix.

Step 4: Decoding at the Receiver.

The decoder for the concatenation system uses a modified SCL decoding algorithm. The essential modification lies in that, in decoding the parity bit, decision is made by checking result based on the decision values of the information bits in the parity function that contains the parity bit, rather than based on the path metrics as in the original SCL decoding algorithm.

The decoding process comprises specifically the following steps.

Initialization of the input: i=1, and the maximum number of paths in the decoder is L.

In Step 1, it is determined whether i is less than or equal to N. If so, proceed to Step 2. Otherwise, proceed to Step 7.

In Step 2, it is determined whether uᵢ is a frozen bit. If so, proceed to Step 3.

Otherwise, proceed to Step 4.

In Step 3, the decision value for uᵢ on each current path is set to 0. Let i=i+1 and return to Step 1.

In Step 4, it is determined whether uᵢ is the j(1≤j≤K)^{th} parity bit. If so, proceed to Step 5. Otherwise, proceed to Step 6.

In Step 5, the decision value for uᵢ on each current path is obtained by checking result based on the decision values of the information bits on the path:

$${\hat{u}}_{i} = ( {\sum }_{h ∈ \{ {A}_{{T}_{j}} \backslash ma x ( {A}_{{T}_{j}} ) \}} {\hat{u}}_{h} ) mod 2.$$

Let i=i+1 and return to Step 1.

In Step 6, the number of current paths is denoted as L′, and uᵢ on each current path may be assigned with a value of 0 or 1, so as to obtain 2L′ subpaths. The path metrics of the 2L′ subpaths are respectively the probabilities of assigning a value of 0 or 1 to uᵢ on the paths: W_{N}⁽ⁱ⁾(y₁^{N},û₁ⁱ⁻¹|0) or W_{N}⁽ⁱ⁾(y₁^{N},û₁ⁱ⁻¹|1). If 2L′≤L, the 2L′ subpaths are reserved. If 2L′>L, the L subpaths with the maximum path metrics are reserved. Let i=i+1 and return to Step 1.

In Step 7, the decision sequence û₁^{N} for the path with the maximum path metric out of the L paths is output.

In Step 8: End.

In the decoding result û₁^{N}, \hat{x}₁^{M+K}=û_{A} is the decoding result for the outer codeword. Let the set I={i|i=1, 2, 3, . . . , M+K, i∉P}, then \hat{x}_{I} is the decoding result for the transmitted information bits.

The error-correction coding method concatenating a polar code with a multi-bit parity-check code according to the disclosure will be explained below in detail in conjunction with an embodiment.

In this embodiment, the concatenated codeword length is N=512, the number of information bits is M=240, and the number of parity bits is K=16, from which it is known that the number of unfrozen bit channels in the inner polar code is 256, and the number of frozen bit channels in the inner polar code is 256. Assume that polar code is constructed at the signal-to-noise ratio 2 dB, a set of indexes of the unfrozen bit channels A={a₁, a₂, a₃, . . . , a₂₅₆ }⊆{1, 2, 3, . . . , 512} and a set of indexes of the frozen bit channels A^{c} are obtained respectively. The decoder at the receiver uses the modified SCL decoding algorithm, with the maximum number of paths set to L=32.

Step 1: Encoding by the Outer Encoder.

Assume that the number of information bits is 240, and the number of parity bits is 16, then the codeword length of the outer code is 256, and the outer codeword is denoted as x₁²⁵⁶. In an embodiment, a set P of indexes of the parity bits is obtained as follows by using respectively the three methods described above for determining the set P:

In Method 1, the parity bits are concentrated at the end of the outer codeword. Specifically, among the bits in the outer codeword x₁²⁵⁶, the last 16 bits, i.e., x₂₄₁²⁵⁶, are parity bits, and the first 240 bits, i.e., x₁²⁴⁰, are information bits. Accordingly, a set P={241,242,243,244,245,246,247,248,249,250,251,252,253,254,255,256} is obtained.

In Method 2, the parity bits are distributed uniformly in the outer codeword. Specifically, among the bits in the outer codeword x₁²⁵⁶, x_{1×16}, x_{2×16}, x_{3×16}, . . . , x_{16×16} are parity bits, and the other 240 bits are information bits. Accordingly, a set P={16,32,48,64,80,96,112,128,144,160,176,192,208,224,240,256} is obtained.

In Method 3, the parity bits are distributed non-uniformly in outer codeword. Assume that the parity bits are distributed non-uniformly in such a manner that the number of parity bit concentrated at the end is K₁=8, and the number of parity bits distributed uniformly at the front is K−K₁=8. As such, among the bits in the outer code x₁²⁵⁶, x_{1×31}, x_{2×31}, x_{3×31}, . . . , x_{8×31}, x₂₄₉, x₂₅₀, x₂₅₁, . . . , x₂₅₆ are parity bits, and the other 240 bits are information bits. In this example, a set P={31,62,93,124,155,186,217,248,249,250,251,252,253,254,255,256} is obtained.

Taking a set P obtained by using Method 2 as an example, the determination of information bit indexes in each parity function and encoding of each parity function will be described.

Given P={16,32,48,64,80,96,112,128,144,160,176,192,208,224,240,256}, i.e., the parity bit in the first parity function is x₁₆, all the bits in this function will be selected from the set S₁={1, 2, 3, . . . , 16}, and the index p₁=16 of the parity bit is necessarily selected. Each element in the set S₁\max(S₁) is selected as a participant for the parity function or not with a probability of α=0.5, then, one can obtain the index set T₁={6,8,10,11,16} corresponding to the first parity function, and accordingly, the coding formula for the first parity bit x₁₆ is:

x₁₆=x₆⊕x₈⊕x₁₀⊕x₁₁ (1)

The value of the other 15 parity bits may also be determined in the manner described above, and then encoding of the outer code is completed.

Step 2: Outer Codeword Mapping.

It is known that the codeword obtained by the outer encoder is x₁²⁵⁶, and the index set of unfrozen bit channels in the polar code is A={a₁, a₂, a₃, . . . , a₂₅₆}. The 1^{st} through the 256^{th} bits in the codeword x₁²⁵⁶ are mapped sequentially to the 1^{st} through the 256^{th} unfrozen bits in the polar code, resulting in an unfrozen bit sequence u_{A}=x₁²⁵⁶ in the polar code.

It is known after mapping that parity bits in the outer codeword are transmitted over the unfrozen bit channels Aₚ={aᵢ|i∈P}, the j(j=1, . . . , 16)^{th} parity bit in the outer codeword is transmitted over the unfrozen bit channel aₚ_{ⱼ}, and all the bits in the j^{th} parity function of the outer codeword are transmitted over the unfrozen bit channels A_{T}_{ⱼ}={aᵢ|i∈Tⱼ}. Taking P={16,32,48,64,80,96,112,128,144,160,176,192,208,224,240,256} obtained by using Method 2 as an example, parity bits in the outer codeword are transmitted over the unfrozen bit channels

A_{P}={aᵢ|i∈P}={a₁₆,a₃₂,a₄₈,a₆₄,a₈₀,a₉₆,a₁₁₂,a₁₂₈,a₁₄₄,a₁₆₀,a₁₇₆,a₁₉₂,a₂₀₈,a₂₂₄,a₂₄₀,a₂₅₆}; the 1^{st} parity bit in the outer codeword is transmitted over the unfrozen bit channel aₚ=a₁₆; and all the bits in the first parity function of the outer codeword are transmitted over the unfrozen bit channels A_{T}_{₁}={aᵢ|i∈T₁}={a₆,a₈,a₁₀,a₁₁,a₁₆}. The values of A_{T}_{ⱼ}, aₚ_{ⱼ}, (j=2, 3, 4, . . . , 16) are obtained sequentially.

Step 3: Encoding by the Inner Encoder.

The unfrozen bit sequence in the inner polar code obtained in Step 2 is u_{A}=x₁²⁵⁶, and the frozen bit sequence in the polar code is comprised totally of 0s, from which the polar encoding bit sequence u₁⁵¹² is derived. Based on the polar coding formula, a codeword encoded by the concatenation system c₁⁵¹²=u₁⁵¹²G₅₁₂ is obtained, where G₅₁₂ is a generator matrix of a polar code of length 512.

Step 4: Decoding by the Concatenation System.

A modified SCL decoding algorithm is used for decoding by the concatenation system. The essential difference between this algorithm and the original SCL decoding algorithm lies in that, in decoding a parity bit, the decision value for the parity bit is obtained directly by checking result based on the decision values of the information bits in the parity function. Taking the first parity function as an example, when decoding the bit uₐ_{₁₆}, decision for the bit uₐ_{₁₆} in 32 paths is obtained by checking result based on the decision values of the information bits in the first parity function, using a formula of:

ûₐ_{₁₆}=ûₐ_{₆}⊕ûₐ_{₈}⊕ûₐ_{₁₀}⊕ûₐ_{₁₁} (2)

For decision of a bit other than parity bits, decision is made according to the conventional SCL decoding algorithm. According to this modified SCL decoding algorithm, a decoding result û₁⁵¹² is obtained for the concatenated code. In the decoding result û₁⁵¹², \hat{x}₁^{M+K}=û_{A} is the decoding result for the outer codeword. Let the set I={i|i=1, 2, 3, . . . , 256, i∉P}, then \hat{x}_{I} is the decoding result for the transmitted information bits.

While particular embodiments of the invention have been shown and described, it will be obvious to those skilled in the art that changes and modifications may be made without departing from the invention in its broader aspects, and therefore, the aim in the appended claims is to cover all such changes and modifications as fall within the true spirit and scope of the invention.

The invention claimed is:

1. An error-correction coding method, the method comprising:
(1) performing repetition coding or multi-bit parity-check coding on an information bit sequence, to yield an outer codeword;
(2) sequentially mapping a first bit to a last bit of the outer codeword on a first unfrozen bit to a last unfrozen bit of a polar code, to yield an unfrozen bit sequence; and
(3) performing polar coding on the unfrozen bit sequence, to yield a concatenated codeword.

2. The method of claim 1, wherein in (1), an information bit to be repeated is repeated one or more times during the repetition coding.

3. The method of claim 2, wherein in (2), in the process of mapping, the bit channel capacities of unfrozen bit channels mapped by repeated bits are lower than those of the unfrozen bit channels mapped by unrepeated bits, where the repeated bits denote the information bits that are repeated in the repetition coding, and the unrepeated bits denote the information bits that are not repeated.

4. The method of claim 3, wherein in (2), in the process of mapping, the indexes of the unfrozen bits mapped by repeating bits of the outer codeword are greater than the index of the unfrozen bit mapped by the repeated bit corresponding to the repeating bits, where the repeating bits denotes the bits in the repetition code that repeat the repeated bit.

5. The method of claim 4, wherein the repeating bits of the outer codeword are distributed uniformly or approximately uniformly in the unfrozen bit sequence.

6. The method of claim 5, wherein by dividing the unfrozen bit sequence into S segments in the order of the indexes, the repeating bits of the outer codeword are mapped to Kₕ unfrozen bit channels of the lowest bit channel capacities in each segment, with the same number or approximately the same number of repeating bits in each segment, such that the repeating bits of the outer codeword are distributed uniformly or approximately uniformly in the unfrozen bits, where h=1, 2, . . . , S.

7. The method of claim 4, wherein:
the outer codeword is an inverted repetition code;
when the repeated bit is 1, the repeating bit of the inverted repetition code is 0, and when the repeated bit is 0, the repeating bit of the inverted repetition code is 1; and
when the repeated bit is repeated for K times, the number of inversed repeating bits out of the K repeating bits obtained by repetition coding is 0˜K.

8. The method of claim 4, wherein certain bits at an end of the outer codeword are used as parity bits, and each of the parity bits serves as an even or odd-parity bit for information bits corresponding to the parity bit, where an even parity bit denotes a bit whose value is 0 (or 1) if the number of is in its corresponding information bits is even (or odd), an odd parity bit denotes a bit whose value is 1 (or 0) if the number of 1s in its corresponding information bits is even (or odd).

9. The method of claim 4, wherein the error-correction coding method further comprises a decoding process as follows: (4) deciding an original information bit according to the SCL decoding algorithm; and deciding the repeating bit directly based on a decision result of the repeated bits.

10. The method of claim 9, wherein the decoding process comprises:
(4.1): determining whether i is less than or equal to N; and if so, proceeding to (4.2), otherwise, proceeding to (4.7);
where N is a codeword length of a concatenated code, and i is an index of an i th bit currently being decoded, and has an initial value of 1 and is assigned with a positive integer from 1 to N;
(4.2): determining whether uᵢ is a frozen bit, and if so, proceeding to (4.3), otherwise, proceeding to (4.4), where uᵢ is the i th bit in the polar encoding bit sequence u₁^{N} and u₁^{N} is a row vector (u₁, u₂, u₃, . . . , u_{N}) in 1×N;
(4.3): setting a decision value for uᵢ on each path to a value of a known frozen bit, letting i=i+1, and returning to (4.1);
(4.4): determining whether uᵢ is a repeating bit of the j(1≤j≤K) th repetition code, and if so, proceeding to (4.5), otherwise, proceeding to (4.6), where K is the number of repeated bits in the outer code, and the outer code contains K repetition codes, each of which consists of a repeated bit and the repeating bits corresponding to the repeated bit, and the j(1≤j≤K) th repetition code in the outer code denotes the repetition code containing the j th repeated bit;
(4.5): setting the decision value for the repeating bits uᵢ on each current path to the decision value of the repeated bit corresponding to uᵢ on the path, specifically,
$${\hat{u}}_{i} = {\hat{u}}_{m i n ( {A}_{{T}_{j}} )} ,$$
letting i=i+1, and returning to (4.1);
where Tⱼ is a set of indexes of all the bits in the j th repetition code in the outer codeword, A_{T}_{ⱼ} is a set of indexes of all the bits in the j th repetition code in the polar encoding bit sequence u₁^{N} after outer codeword mapping, and min(A_{T}_{ⱼ}) is a minimum element in the value set A_{T}_{ⱼ} and corresponds to the repeated bit in the j th repetition code; min(X) denotes a minimum value in the value set X;
(4.6): denoting the number of current paths as L′, obtaining 2L′ subpaths by assigning a value of 0 or 1 to uᵢ on each current path, and determining whether 2L′≤L is satisfied, and if so, reserving 2L′ subpaths, otherwise, reserving L subpaths with the maximum path metrics, letting i=i+1 and returning to (4.1);
where the metrics of the 2L′ subpaths are respectively the probabilities W_{N}⁽ⁱ⁾(y₁^{N},û₁ⁱ⁻¹|0) or W_{N}⁽ⁱ⁾(y₁^{N},û₁ⁱ⁻¹|1) of assigning 0 or 1 to uᵢ on the paths, L is the maximum number of paths in the SCL decoding algorithm, and y₁^{N} denotes the received vector; and
(4.7): obtaining a decoding result by outputting a decision sequence û₁^{N} corresponding to the path with the maximum path metric out of the L paths.

11. The method of claim 1, wherein:
the parity bits of the outer codeword obtained by performing multi-bit parity-check coding on the information bit sequence in (1) are concentrated at the end of the outer codeword;
the set of indexes of the parity bits is P={M+1, M+2, M+3, . . . , M+K}, and the elements in the set P represent the bit indexes in the outer codeword where the parity bits are located; that is, in the codeword x₁^{M+K} generated by an outer encoder, the bit sequence x₁^{M} is information bits, and the bit sequence x_{M+1}^{M+K} is parity bits; and
where M is a number of information bits, and K is a number of parity bits.

12. The method of claim 1, wherein:
the parity bits of the outer codeword obtained by performing multi-bit parity-check coding on the information bit sequence in (1) are distributed uniformly in the outer codeword;
the interval between adjacent parity bits is
$$⌊ \frac{M + K}{K} ⌋ ,$$
and the set of indexes of the parity bits is
$$P = \{ ⌊ \frac{M + K}{K} ⌋ \cdot j , j = 1 , 2 , 3 , … , K \} ;$$
and
where M is a number of information bits, K is a number of parity bits, M+K is the outer codeword length, and └x┘ is a floor function of x.

13. The method of claim 1, wherein the parity bits of the outer codeword obtained by performing multi-bit parity-check coding on the information bit sequence in (1) are distributed non-uniformly in the outer codeword.

14. The method of claim 13, wherein assuming that the number of parity bits concentrated at the end of the outer codeword is K₁, then the number of preceding parity bits distributed uniformly is K−K₁, and the set of indexes of the parity bits is:
$$P = \{ {P}_{1} {UP}_{2} \vert {P}_{1} = \{ M + K - {K}_{1} + 1 , M + K - {K}_{1} + 2 , … , M + K \} , {P}_{2} = \{ ⌊ \frac{M + K - {K}_{1}}{K - {K}_{1}} ⌋ \cdot j , j = 1 , 2 , 3 , … , K - {K}_{1} \} \} ;$$
where M is the number of information bits, and K is the number of parity bits

15. The method of claim 1, wherein when multi-bit parity-check coding is performed on the information bit sequence in (1), the parity bit is used only to check the information bits before and not the information bits after.

16. The method of claim 15, wherein the outer code is replaced with a multi-bit odd-parity code, whose parity bits are odd parity bits.

17. The method of claim 15, wherein the decoding process for the coding method described above is performed by using a modified SCL decoding algorithm; in decoding the information bit, bit decision is performed according to the conventional SCL decoding algorithm, and in decoding the parity bit, decision is made by checking result based on the decision values of the information bits in the parity function containing the parity bit, where a parity function denotes the mathematical relationship between a parity bit and its corresponding information bits.

18. The method of claim 17, wherein the decoding process comprises:
step 1: determining whether i is less than or equal to N, and if so, proceeding to step 2, otherwise, proceeding to step 7, where N is the codeword length of the concatenated code, and i is the index of the i^{th} bit being decoded, and has an initial value of 1 and is assigned with a positive integer from 1 and N;
step 2: determining whether uᵢ is a frozen bit, and if so, proceeding to step 3, otherwise, proceeding to step 4, where uᵢ is the i th bit in the polar encoding bit sequence;
step 3: setting the decision value for uᵢ on each current path to the value of a known frozen bit, letting i=i+1, and returning to step 1;
step 4: determining whether uᵢ is the j(j=1, 2, . . . , K) th parity bit, and if so, proceeding to step 5, otherwise, proceeding to step 6, where K is the number of parity bits;
step 5: obtaining a decision value for uᵢ on each current path by checking result based on the decision values of the information bits on the path:
$${\hat{u}}_{i} = ( {\sum }_{h ∈ {A}_{{T}_{j}} \backslash ma x ( {A}_{{T}_{j}} )} {\hat{u}}_{h} ) mod 2 ,$$
letting i=i+1, and returning to step 1; where Tⱼ is a set of indexes of all the bits from the j th parity function in the outer code, and the outer code contains K parity functions, each of which consists of a parity bit and the information bits corresponding to the parity bit, and the j th parity function denotes a parity function containing the i th parity bit, A_{T}_{ⱼ} is a set of indexes of all the bits from the j th parity function in the polar encoding bit sequence u₁^{N} after outer codeword mapping, max(A_{T}_{ⱼ}) denotes the maximum element in the value set A_{T}_{ⱼ} and is the index of the parity bit from the j th parity function mapped into u₁^{N}; h is a temporary variable in said sum operation, denoting each element in the set A_{T}_{ⱼ}\max(A_{T}_{ⱼ}) sequentially, and A_{T}_{ⱼ}\max(A_{T}_{ⱼ}) denotes the difference between the value sets A_{T}_{ⱼ} and max(A_{T}_{ⱼ}), where A_{T}_{ⱼ}\max(A_{T}_{ⱼ})={λ|λ∈A_{T}_{ⱼ},λ≠max(A_{T}_{ⱼ})};
max(X) denotes the maximum element in the value set X, and {X\Y} denotes the difference between the value sets X and Y, {X\Y}={λ|λ∈X,λ∉Y};
step 6: denoting the number of current paths as L′, and obtaining 2L′ subpaths by assigning a value of 0 or 1 to uᵢ on each current path, where the path metrics for the 2L′ subpaths are respectively the probabilities W_{N}⁽ⁱ⁾(y₁^{N},û₁ⁱ⁻¹|0) or W_{N}⁽ⁱ⁾(y₁^{N},û₁ⁱ⁻¹|1) of assigning 0 or 1 to uᵢ on the paths;
if 2L′≤L, reserving 2L′ subpaths, otherwise, if 2L′>L, reserving L subpaths with the maximum path metrics, letting i=i+1 and returning step 1;
where L is the maximum number of paths in the SCL decoding algorithm, and y₁^{N} denotes the received vector;
step 7: outputting the decision sequence û₁^{N} corresponding to the path with the maximum path metric out of the L paths; and
step 8: end.
